(19) United States
(12) Patent Application Publication
(10) Pub. No.: US 2025/0386422 A1
(43) Pub. Date: Dec. 18, 2025

(54) APPARATUSES AND METHODS FOR PROVIDING POWER TO ELECTRONIC DEVICES

(71) Applicant: General Dynamics Mission Systems, Inc., Fairfax, VA (US)

(72) Inventors: Matthew M. Foster, Chandler, AZ (US); Eric Jon Stefanowicz, Scottsdale, AZ (US)

(73) Assignee: General Dynamics Mission Systems, Inc., Fairfax, VA (US)

(21) Appl. No.: 18/744,153

(22) Filed: Jun. 14, 2024

(51) Int. Cl. H05K 1/02

(52) U.S. Cl. CPC H05K 1/0218; H05K 1/0233; H05K 1/0298

(57) ABSTRACT

Apparatuses and methods are provided for providing electrical power to electronic devices. The apparatuses include a printed circuit board (PCB) having a power circuit and a sense circuit electrically isolated from each other, an integrated circuit (IC) having an IC power plane, power pins electrically coupled to the power circuit, and an isolated pin electrically coupled to the sense circuit, wherein the power pins are electrically coupled to the isolated pin via the IC power plane, and a voltage regulator having output pins electrically coupled to the power circuit and a sense pin electrically coupled to the sense circuit, wherein the voltage regulator is configured to provide electrical power to the IC via the power circuit, sense a load variation at the sense pin, and regulate a voltage of the electrical power based on the load variation sensed.

### TECHNICAL FIELD OF THE INVENTION

The technical field generally relates to powering integrated circuits, and more particularly relates to devices having voltage regulators with a sense line directly coupled to an integrated circuit in a manner that provides for the voltage of the sense line to match a voltage of a power plane of the integrated circuit.

### BACKGROUND OF THE INVENTION

This section provides background information related to the present disclosure which is not necessarily prior art.

A voltage regulator is a circuit configured to establish and maintain a fixed output voltage, regardless of fluctuations in the input voltage or changes in load conditions. As voltage regulators are often quite a distance away from the devices that they supply power to, there is often a drop in voltage along the path from the regulator to the main points-of-load, particularly under high current demand. If the regulator was not accounting for this drop, the voltage at the point-of-load may deviate from what the regulator perceives. Consequently, the resulting lower voltage might fall outside the necessary range for proper device functionality.

To mitigate this issue, regulators may connect to a high impedance sense line. These sense lines carry a negligible amount of current and as such the voltage observed by the regulator more closely matches the voltage at the point-of-load. This enables the regulator to more accurately adjust its output voltage as needed, ensuring that the voltage at the point-of-load is within the required specifications. However, even with the use of a sense line, there may still be a voltage drop between the sensed location and the point-of-load. As integrated circuits continue to be reduced in size and require increased current demands, the voltage tolerance needed for reliably operating the integrated circuits is narrowing.

Accordingly, there is an ongoing desire for apparatuses and methods that are capable of more precisely regulating the voltage of electrical power provided to integrated circuits to promote reliability thereof. Furthermore, other desirable features and characteristics of the present disclosure will become apparent from the subsequent detailed description and the appended claims, taken in conjunction with the accompanying drawings and the foregoing introduction.

### SUMMARY OF THE INVENTION

This section provides a general summary of the disclosure and is not a comprehensive disclosure of its full scope or all of its features.

In various examples, an apparatus is provided that includes a power source for providing electrical power, a point-of-load for receiving the electrical power from the power source via a power circuit, and a sense circuit directly connecting the power source to the point-of-load, wherein the power source is configured to sense a load variation via the sense circuit and regulate a voltage of the electrical power provided therefrom based on the sensed load variation, wherein the sense circuit and the power circuit are electrically coupled solely through the point-of-load.

In various examples, an apparatus is provided that includes a printed circuit board (PCB) having a power circuit and a sense circuit that are electrically isolated from each other within the PCB, an integrated circuit coupled to the PCB and having an IC power plane, one or more power pins, and an isolated pin, wherein the one or more power pins are electrically coupled to the isolated pin via the IC power plane, wherein the one or more power pins are electrically coupled to the power circuit of the PCB and the isolated pin is electrically coupled to the sense circuit, and a voltage regulator coupled to the PCB and having one or more output pins and a sense pin, wherein the one or more output pins are electrically coupled to the power circuit of the PCB and the sense pin is electrically coupled to the sense circuit of the PCB, wherein the voltage regulator is configured to provide electrical power to the integrated circuit via the power circuit, sense a load variation at the sense pin, and regulate a voltage of the electrical power based on the load variation sensed.

In various examples, a method is provided that includes providing electrical power from one or more output pins of a voltage regulator to a power circuit of a printed circuit board (PCB), from the power circuit to one or more power pins of an integrated circuit, and from the one or more power pins to an IC power plane of the integrated circuit, wherein the electrical power is sufficient to operate the integrated circuit, receiving the electrical power from the IC power plane to an isolated pin of the integrated circuit, from the isolated pin to a sense circuit of the PCB, and from the sense circuit to a sense pin of the voltage regulator, wherein the power circuit and the sense circuit are electrically isolated from each other within the PCB, sensing a load variation at the sense pin with a sensing device of the voltage regulator, and regulating a voltage of the electrical power with the voltage regulator based on the load variation sensed at the sense pin.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

The drawings described herein are for illustrative purposes only of selected embodiments and not all possible implementations and are not intended to limit the scope of the present disclosure.

FIG. 1 is a schematic wiring diagram illustrating exemplary electrical connections between components of a device in accordance with certain aspects of an embodiment;

FIG. 2 is a cross-sectional view of a portion of an exemplary device in accordance with certain aspects of an embodiment; and

FIG. 3 is a flowchart illustrating an exemplary method for providing electrical power to an integrated circuit in accordance with certain aspects of an embodiment.

Corresponding reference numerals indicate corresponding parts throughout the several views of the drawings.

### DETAILED DESCRIPTION

Example embodiments will now be described more fully with reference to the accompanying drawings.

Briefly, systems and methods disclosed herein provide for supplying electrical power to electronic devices (e.g., integrated circuits (ICs)) within a relatively narrow voltage range to promote reliable operation of the electronic devices. The systems include an electronic device (referred to hereinafter as an integrated circuit for convenience) with an IC power plane therein for distribution of electrical power to components (e.g., active devices such as transistors) of the integrated circuit. The systems also include a voltage regulator (also referred to as the source), such as a switching voltage regulator or a linear voltage regulator, configured to provide electrical power to the IC power plane of the integrated circuit. The voltage regulator includes a voltage sense input configured to sense a voltage of the IC power plane at a point-of-load and regulate the electrical power based on the load variation sensed.

Voltage regulators establish and maintain a fixed output voltage, regardless of fluctuations to the input voltage or changes in load conditions. A switching voltage regulator, in particular, is a voltage regulator that uses a switching element to transform the incoming power supply into a pulsed voltage, which may then be smoothed using capacitors, inductors (e.g., power inductors), and/or other elements. Switching regulators promote efficient generation of stable supply voltages and the translation of voltages up or down.

Power inductors are passive electronic components that store electrical energy in a magnetic field to ensure that electronic products maintain a consistent voltage level and current draw, and convert an input voltage waveform to a different output voltage waveform. Power inductors may be used with a switching voltage regulator to, for example, convert a direct current (DC) that is switched on-and-off to a lower valued direct current (DC).

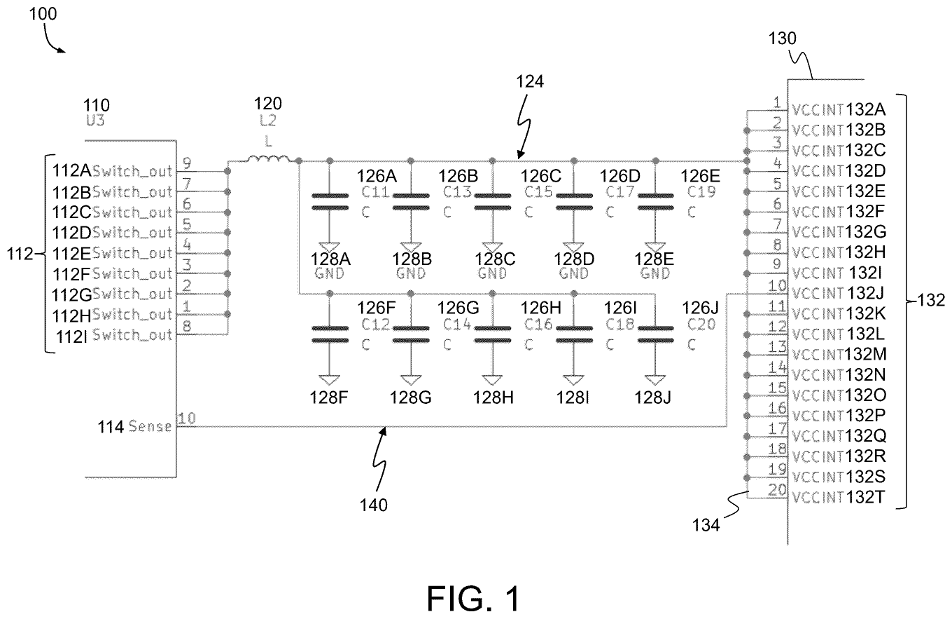

As an example, FIG. 1 provides a schematic wiring diagram of an apparatus 100 illustrating exemplary electrical connections between a switching voltage regulator 110 and an integrated circuit 130. In this example, the switching voltage regulator 110 (also labeled “U3”) includes a bank 112 of output pins 112A-112| (also labeled “Switch_out 1-9”) and a sense pin 114 (also labeled “Sense”). The switching voltage regulator 110 may be configured to regulate the voltage output through the bank of output pins 112 based on a voltage at the sense pin 114. The bank of output pins 112 provide electrical power to an inductor 120 (also labeled “L2”), which then outputs the electrical power to a PCB power plane 124 of a PCB. The PCB power plane 124 may be coupled to one or more capacitors 126A-126J (also labeled “C11-C20”) which in turn may be coupled to ground connections 128A-128J (also labeled “GND); e.g., to a ground plane of the PCB). The integrated circuit 130 includes a bank 132 of power pins 132A-132T (also labeled “VCCINT 1-20”) that are coupled with an IC power plane of the integrated circuit 130. The PCB power plane 124 of the PCB provides the electrical power to the IC power plane of the integrated circuit 130 via one or more of the power pins 132A-1321 and 132K-132T of the bank 132. The sense pin 114 is electrically connected directly to an isolated power pin 132J (i.e., VCCINT 10) of the bank 132 by a dedicated sense circuit 140. The isolated power pin 132J is electrically connected to the IC power plane of the integrated circuit 130, and is not directly coupled to the other power pins 132A-1321 and 132K-132T within the bank 132. In addition, the dedicated sense circuit 140 is not directly connected to the PCB power plane 124 (i.e., the sense circuit 140 is electrically isolated from the PCB power plane 124 within the PCB).

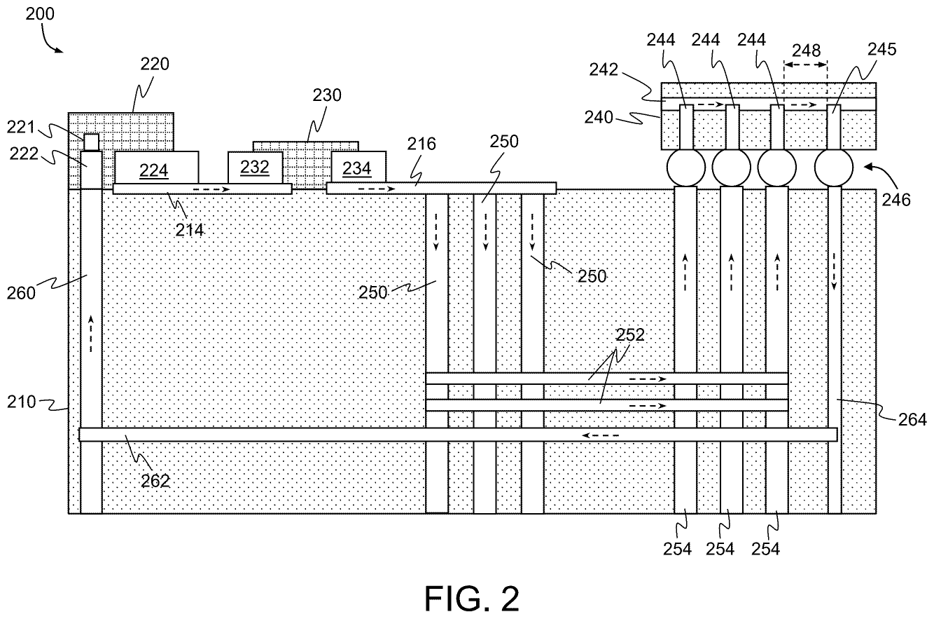

Referring now to FIG. 2, a cross-sectional view of a portion of an exemplary device 200 is provided that includes a printed circuit board (PCB) 210 having a switching voltage regulator 220, an inductor 230, and an integrated circuit 240 secured to a surface thereof. The PCB 210 may include a single layer or a stack of two or more layers each formed of various materials, such as certain laminate materials. In various examples, the PCB 210 includes a multilayer stack that includes four or more layers. Although not shown, the switching voltage regulator 220 is configured to receive electrical power from a power source, such as a power supply. In some examples, one or more of the components of FIG. 2 may be components of a power supply.

The switching voltage regulator 220 is coupled to a first trace 214 of the PCB 210 with one or more switching voltage regulator output pins 224. The Inductor 230 is coupled to the first trace 214 of the PCB 210 with one or more inductor input pins 232 and coupled to a second trace 216 of the PCB 210 with one or more inductor output pins 234. The second trace 216 is coupled to a first set of power vias 250 of the PCB 210. The first power vias 250 are coupled to one or more layers that define a PCB power plane 252 of the PCB 210. The PCB power plane 252 is coupled to second power vias 254 of the PCB 210. The power plane 252 is coupled to the integrated circuit 240 by with a plurality of power contacts of a ball grid array 246 which in turn are each coupled to an IC power plane 242 within the integrated circuit 240 by first IC connections 244. In some examples, the PCB 210 may include a ground plane configured to couple circuits and devices of the PCB 210 to ground.

In this example, the first power vias 250, the PCB power plane 252, and the second power vias 254 define a power distribution circuit that forms a continuous circuit between the second trace 216 and the plurality of power contacts of the ball grid array 246. Although FIG. 2 represents the power distribution circuit as including three of the first power vias 250, three of the second power vias 254, and two layers of the PCB power plane 252, the power distribution circuit may include fewer or more of each of these conductive elements, and/or may include additional conductive elements not represented in FIG. 2.

The integrated circuit 240 also includes a second IC connection 245 that couples the IC power plane 242 to an isolated contact of the ball grid array 246 which in turn is coupled to a second sense via 264 of the PCB 210. The second sense via 264 is coupled to an inner trace 262 of the PCB 210. The inner trace 262 is coupled to a first sense via 260 which is further coupled to a sense pin 222 of the switching voltage regulator 220. In this example, the second via 264, the inner trace 262, and the first sense via 260 define a sense circuit that forms a continuous circuit between the sense pin 222 of the switching voltage regulator 220 and the second IC connection 245 of the integrated circuit 240. In some examples, the sense circuit may include additional conductive elements not represented in FIG. 2.

During operation of the apparatus 200, the switching voltage regulator 220 is configured to provide electrical power to inductor 230 through the connection therebetween defined by the switching voltage regulator output pin(s) 224 the first trace 214, and the inductor input pin(s) 232. The inductor 230 is configured to receive the electrical power from the switching voltage regulator 220 and output the electrical power to the PCB power plane 252 of the PCB 210 via the inductor output pin(s) 234 and the second trace 216. The power distribution circuit is configured to receive the electrical power from the inductor 230 and provide the electrical power to the integrated circuit 240 through the interface therewith defined by the ball grid array 246. The electrical power is thereafter received at the IC power plane 242 via the first IC connections 244 and distributed as needed to active components of the integrated circuit 240. The path of the electrical power is represented in FIG. 2 with arrows.

The sense circuit receives the electrical power from the IC power plane 242 and provides the electrical power to the sense pin 222 of the switching voltage regulator 220. In this example, the sense circuit is electrically isolated from the PCB power plane 252 within the PCB 210, and the second IC connection 245 of the integrated circuit 240 is not directly connected to the PCB power plane 252 of the PCB 210 or to the first IC connections 244. As such, the voltage of the electrical power at the sense pin 222 is substantially the same as the voltage at the IC power plane 242.

The switching voltage regulator 220 is configured to regulate the voltage of the electrical power provided to the integrated circuit 240 based on the voltage sensed by a sensing device 221 coupled to the sense pin 222. That is, the switching voltage regulator 220 may output the electrical power from the switching voltage regulator output pin 224 at sufficiently high voltage to substantially accommodate for a drop in voltage between the switching voltage regulator 220 and the IC power plane 242 of the integrated circuit 240 wherein the voltage at the IC power plane 242 is within a predetermined range. Since the sense pin 222 has substantially the same voltage as the IC power plane 242 at the point of connection with the second IC connection 245, the drop in voltage between the provided voltage and the voltage received by active components of the integrated circuit 240 may be limited to a dimension 248 (FIG. 2), and therefore the switching voltage regulator 220 is capable of providing the electrical power to the components (e.g., the active devices) of the integrated circuit 240 within a relatively narrow range about a predetermined operating voltage.

The systems, devices, and components disclosed herein may be manufactured using various processes and may be formed of or include various materials. Various such processes and materials are well known to those skilled in the art and therefore will not be discussed in detail herein. As an example, the various conductive paths (e.g., the traces, vias, power planes, etc.) may include one or more layers of various materials, such as certain metallic materials (e.g., copper or copper alloy) that provide a low-impedance path for delivering the electrical power to various components.

Although the apparatus 200 is represented and described with use of the switching voltage regulator 220, it should be understood that aspects of the apparatus 200 may be applicable to apparatuses using other types of voltage regulators. For example, the switching voltage regulator 220 may alternatively be a linear voltage regulator. In such apparatuses, the inductor 230 and the second trace 216 may be omitted, and the first trace 214 may connect the voltage regulator output pins 224 directly to the first power vias 250.

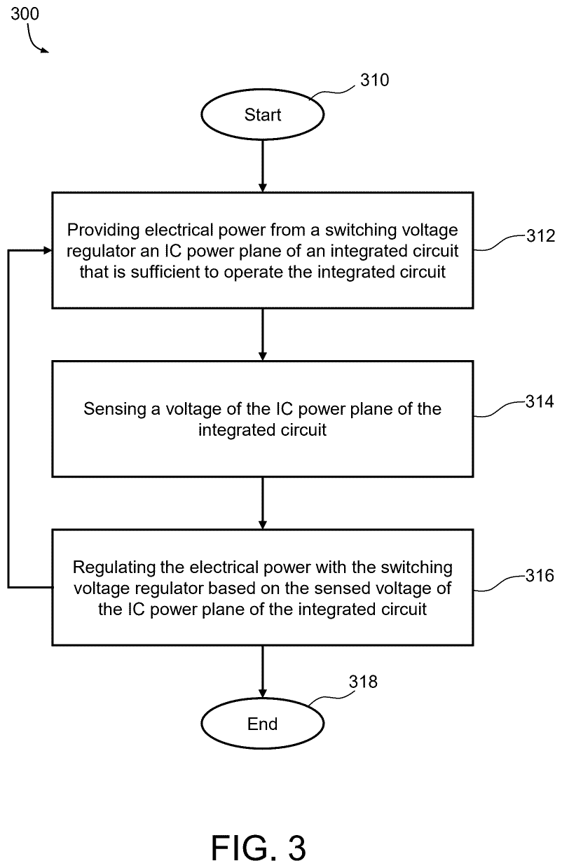

The systems and devices disclosed herein, including the apparatus 100 and the apparatus 200, provide for methods of regulating the voltage of electrical power provided to an electronic device (e.g., an integrated circuit). For example, FIG. 3 is a flowchart illustrating an exemplary method 300 for operating an apparatus to provide electrical power to an electronic device (referred to hereinafter as an integrated circuit) of the apparatus. The method 300 may start at 310. In some examples, the method 300 may start upon turning on the apparatus.

At 312, the method 300 may include providing electrical power from a voltage regulator, such as a switching voltage regulator or a linear voltage regulator, to an IC power plane of an integrated circuit that is sufficient to operate the integrated circuit. In some examples, the method 300 may include assembling various components of the apparatus. For example, the method 300 may include coupling the voltage regulator to a printed circuit board (PCB) at a first position thereon and coupling the integrated circuit to the PCB at a second position thereon. In some examples, the method 300 may include providing the electrical power from the switching voltage regulator to a PCB power plane of the PCB, and from the PCB power plane of the PCB to the IC power plane of the integrated circuit. In some examples, the method 300 may include providing the electrical power from the voltage regulator to an inductor electrically coupled between the voltage regulator and the integrated circuit, and providing the electrical power from the inductor to the PCB power plane of the PCB. In some examples, the method 300 includes coupling a sense pin of the voltage regulator and a connection (e.g., an isolated pin) of the integrated circuit by a sense circuit within the PCB that is electrically isolated from the PCB power plane within the PCB. Further, the connection or isolated pin of the integrated circuit may not be directly connected to the PCB power plane of the PCB (e.g., only connected to the PCB power plane through the IC power plane).

At 314, the method 300 may include sensing a voltage of the IC power plane of the integrated circuit with, for example, the sense pin of the voltage regulator. In some examples, the sense circuit may include a first via that is in electrical contact with the sense pin of the voltage regulator, a second via that is in electrical contact with the connection or isolated pin of the integrated circuit, and a trace formed on an inner layer of the PCB that directly connects the first via and the second via. In such examples, sensing the voltage of the IC power plane of the integrated circuit may include receiving the electrical power with the voltage regulator from the IC power plane of the integrated circuit through the first via, the second via, and the trace therebetween.

At 316, the method 300 may include regulating the electrical power with the voltage regulator based on the load variation sensed at the sense pin. Once the voltage regulator has adjusted the voltage as necessary, the method 300 may return to 312 to provide the electrical power to the integrated circuit.

The method 300 may end at 318. In some examples, the method 300 may end upon turning off the apparatus.

The systems and methods disclosed herein provide various benefits over certain existing systems and methods. For example, by bypassing the PCB power plane of the PCB and directly connecting the sense pin of the switching voltage regulator to the IC power plane of the integrated circuit, the switching voltage regulator is able to regulate the electrical power to be within a predetermined operating range as required by the components (e.g., active devices) of the integrated circuit in a manner that is more precise than certain existing systems, especially those that couple the sense pin of the switching voltage regulator to the PCB power plane of the PCB or to a position adjacent to an output of the inductor. More specifically, the voltage at the regulated sense pin may be substantially the same as the voltage at the IC power plane of the integrated circuit. As such, the voltage drop between the point-of-load (e.g., an active device of the integrated circuit) and a predetermined voltage intended to be provided thereto from the voltage regulator may be dictated by a relatively small distance. As such, the voltage regulator may be capable of adjusting the voltage output therefrom to accurately provide voltages within a relatively narrow voltage range.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An apparatus, comprising:
a power source for providing electrical power;
a point-of-load for receiving the electrical power from the power source via a power circuit; and
a sense circuit directly connecting the power source to the point-of-load, wherein the power source is configured to sense a load variation via the sense circuit and regulate a voltage of the electrical power provided therefrom based on the sensed load variation, wherein the sense circuit and the power circuit are electrically coupled solely through the point-of-load.

2. The apparatus of claim 1, wherein the power source is a voltage regulator and the point-of-load is an internal power plane of an electronic device.

3. The apparatus of claim 1, wherein a voltage drop from the power source to the point-of-load is determined by a dimension between a first connection between the power circuit and the point-of-load and a second connection between the point-of-load and the sense circuit.

4. An apparatus, comprising:
a printed circuit board (PCB) having a power circuit and a sense circuit that are electrically isolated from each other within the PCB;
an integrated circuit coupled to the PCB and having an IC power plane, one or more power pins, and an isolated pin, wherein the one or more power pins are electrically coupled to the isolated pin via the IC power plane, wherein the one or more power pins are electrically coupled to the power circuit of the PCB and the isolated pin is electrically coupled to the sense circuit; and
a voltage regulator coupled to the PCB and having one or more output pins and a sense pin, wherein the one or more output pins are electrically coupled to the power circuit of the PCB and the sense pin is electrically coupled to the sense circuit of the PCB, wherein the voltage regulator is configured to provide electrical power to the integrated circuit via the power circuit, sense a load variation at the sense pin, and regulate a voltage of the electrical power based on the load variation sensed.

5. The apparatus of claim 4, wherein the power circuit includes a first power via that is in electrical contact with the one or more output pins of the voltage regulator, a second power via that is in electrical contact with the one or more power pins of the integrated circuit, and a PCB power plane that connects the first power via to the second power via, wherein the voltage regulator is configured to provide the electrical power to the integrated circuit through the PCB power plane.

6. The apparatus of claim 4, wherein the sense circuit includes a first sense via that is in electrical contact with the sense pin of the voltage regulator, a second sense via that is in electrical contact with the isolated pin of the integrated circuit, and a trace formed on an inner layer of the PCB that connects the first via and the second via.

7. The apparatus of claim 4, wherein the voltage regulator is a switching voltage regulator, and the apparatus includes an inductor coupled to the PCB and electrically coupled between the switching voltage regulator and the integrated circuit, wherein the inductor is configured to receive the electrical power from the switching voltage regulator and output the electrical power to the power circuit of the PCB.

8. The apparatus of claim 4, wherein the voltage regulator is a linear voltage regulator, and the linear voltage regulator is directly coupled to the power circuit of the PCB.

9. The apparatus of claim 4, wherein the integrated circuit is coupled to the PCB with a ball grid array, wherein a first set of contacts of the ball grid array electrically contact the power circuit, wherein an isolated contact of the ball grid array electrically contacts the sense circuit.

10. A method, comprising:
providing electrical power from one or more output pins of a voltage regulator to a power circuit of a printed circuit board (PCB), from the power circuit to one or more power pins of an integrated circuit, and from the one or more power pins to an IC power plane of the integrated circuit, wherein the electrical power is sufficient to operate the integrated circuit;
receiving the electrical power from the IC power plane to an isolated pin of the integrated circuit, from the isolated pin to a sense circuit of the PCB, and from the sense circuit to a sense pin of the voltage regulator, wherein the power circuit and the sense circuit are electrically isolated from each other within the PCB;
sensing a load variation at the sense pin with a sensing device of the voltage regulator; and
regulating a voltage of the electrical power with the voltage regulator based on the load variation sensed at the sense pin.

11. The method of claim 10, wherein providing the electrical power includes providing the electrical power from the voltage regulator to a first power via of the PCB that is in electrical contact with the one or more output pins of the voltage regulator, from the first power via to a PCB power plane of the PCB, from the PCB power plane to a second power via of the PCB, and from the second power via to the one or more power pins of the integrated circuit.

12. The method of claim 10, wherein receiving the electrical power includes receiving the electrical power from the IC power plane to a second sense via of the PCB that is in electrical contact with the isolated pin of the integrated circuit, from the second sense via to an inner trace of the PCB, from the inner trace to a first sense via, and from the first sense via to the sense pin of the voltage regulator.

13. The method of claim 10, wherein the voltage regulator is a switching voltage regulator, wherein providing the electrical power includes providing the electrical power from the voltage regulator to an inductor in electrical contact with the one or more output pins of the voltage regulator, and from the inductor to the power circuit of the PCB.

14. The method of claim 10, wherein the voltage regulator is a linear voltage regulator, and providing the electrical power includes providing the electrical power directly from the linear voltage regulator to the power circuit of the PCB.

15. The method of claim 10, wherein providing the electrical power includes providing the electrical power from the power circuit of the PCB to a first set of contacts of a ball grid array connecting the integrated circuit to the PCB, wherein receiving the electrical power includes receiving the electrical power from an isolated contact of the ball grid array to the sense circuit of the PCB.
